(19) United States
(12) Patent Application Publication
(10) Pub. No.: US 2005/0176173 A1
(43) Pub. Date: Aug. 11, 2005

(54) Chip-on-board module, and method of manufacturing the same

(75) Inventors: Naoyuki Shinonaga, Nagano (JP); Hideyuki Akagi, Nagano (JP); Syuuichi Osaka, Nagano (JP)

Correspondence Address: MCDERMOTT WILL & EMERY LLP, 600 13TH STREET, N.W., WASHINGTON, DC, 20005-3096, US

(73) Assignee: Renesas Technology Corp., Tokyo (JP)

(21) Appl. No.: 11/102,737

(22) Filed: Apr. 11, 2005

Related U.S. Application Data
(63) Continuation of application No. 10/252,378, filed on Sep. 24, 2002.
Application No. 10/252,378 is a continuation-in-part of application No. 09/798,943, filed on Mar. 6, 2001, now abandoned.

(30) Foreign Application Priority Data
Aug. 29, 2000 (JP) 2000-259661
Mar. 4, 2002 (JP) 2002-057653

(51) Int. Cl. H01L 21/44

(52) U.S. Cl. 438/106

(57) ABSTRACT

A chip-on-board module has a multilayer interconnection board having die mount sections; dies mounted on respective die mount sections such that a single die is mounted on each die mount section or two or more dies are being stacked and mounted there; bonding pads provided on the multilayer and connected to single dies or uppermost dies; contact pads provided on the multilayer board and connected to corresponding bonding pads; jumper pads provided in proximity to the contact pads and connected to edge terminals of the multilayer board, circuit elements mounted on the multilayer interconnection board, or through holes formed so as to extend across layers of the multilayer board; and molding resin for molding the dies and the pads. The uppermost dies of the respective die mount sections where dies are stacked in two or more layers have passed an electric property test.

### RELATED APPLICATION

This application claims priority from and is a continuation-in-part application of U.S. patent application Ser. No. 09/798,943 filed on Mar. 6, 2001, which is incorporated herein by reference.

### BACKGROUND OF THE INVENTION

1. Field of the Invention

The invention relates to a chip-on-board module, and more particularly to a chip-on-board module in which a semiconductor chip (die), such as a memory chip, a microcomputer chip, or an ASIC chip, is mounted on a multilayer interconnection board, as well as to a method of manufacturing the module.

2. Background Art

FIGS. 11A and 11B are schematic representations showing the configuration of a related-art chip-on-board (hereinafter abbreviated as a “COB”) module serving as an example of a memory module. FIG. 11A is a perspective view showing the overall configuration of the memory module, and FIG. 11B shows that two adjacent ICs of the configuration shown in FIG. 11A are mounted on a multilayer interconnection board.

In the drawings, reference numeral 1 designates a multilayer interconnection board; 2 designates a plurality of IC lead pads which are provided on the multilayer interconnection board and are to be used for fixedly interconnecting leads of ICs, thereby mounting the ICs on the multilayer interconnection board 1; and 3 designates an interconnection pattern routed in the form of a predetermined pattern for establishing electrically connection with the IC lead pads 2 together. In addition to interconnecting the ICs, the interconnection pattern 3 is used for connecting together circuit elements (not shown), such as resistors, capacitors, fuses, and like elements mounted on the multilayer interconnection board. Alternatively, the interconnection pattern 3 is connected to through holes formed so as to extend across the multilayer interconnection board for interconnecting interconnection boards. Alternatively, the interconnection pattern 3 is routed in the form of a predetermined pattern on the surface of the multilayer interconnection board 1 so as to be connected with edge terminals 4 which act as terminals for establishing connection with the outside of the multilayer interconnection board. Reference numeral 5 designates ICs which are mounted on the multilayer interconnection board 1 by means of fixing a plurality of leads 5A onto the IC lead pads 2.

FIG. 12 is a flowchart showing processes for manufacturing the memory module shown in FIG. 11A. Specifically, in step S1, a memory chip (i.e., an unillustrated die) is die-bonded to a known lead frame. Next, in step S2, the die and the lead frame are wire-bonded together. In step S3, the die and the lead frame are molded in resin, thereby forming ICs 5. In step S4, the ICs 5 are subjected to an electric property test, on a per-IC basis. If an IC is determined to be a reject, the IC is discarded in step S5. In contrast, if the IC passes the test, in step S6 the IC is mounted on the multilayer interconnection board 1 in the manner as shown in FIG. 11.

Subsequently, in step S7 the multilayer interconnection board is subjected to an electric property test so as to determine its suitability as a memory module, thus completing manufacturing processes.

FIGS. 13 through 18 are schematic diagrams showing circuit configurations and IC layouts required when, in step S6, the ICs 5 are mounted on the multilayer interconnection board 1. FIGS. 13, 14A, and 14B show a circuit configuration and an IC layout required when nine ICs are mounted on the multilayer interconnection board 1. FIGS. 15, 16A, and 16B show a circuit configuration and an IC layout required when 18 ICs are mounted on the multilayer interconnection board 1. FIGS. 17, 18A, and 18B show a circuit configuration and an IC layout required when 36 ICs are mounted on the multilayer interconnection board 1.

When nine ICs are mounted, the ICs are arranged and mounted on the multilayer interconnection board 1 in such a manner as shown in FIG. 14. The drawing illustrates an example of a two-layer multilayer interconnection board 1. FIG. 14A shows a first-layer interconnection board 1a which serves as a front surface, and FIG. 14B shows a second-layer interconnection board 1b which serves as a rear surface. The nine ICs are divided into two groups: one consisting of four ICs, and the other consisting of five ICs. The group consisting of four ICs (5a1 to 5a4) is arranged on the first-layer interconnection board 1a in the manner as illustrated, and the group consisting of five ICs (5b1 to 5b5) is arranged on the second-layer interconnection board 1b in the manner as illustrated. The first-layer and second-layer interconnection boards 1a and 1b are connected together by way of unillustrated through holes. Reference numeral 50 denotes connection ICs that are provided on the first-layer interconnection board 1a and are to be used for establishing connection with external circuits by way of the edge terminals 4.

The multilayer interconnection boards have a circuit configuration such as that shown in FIG. 13. Clock signals (i.e. , Add, CKEO, /SO-3, and the like) and I/O signals (DQ0 . . . and the like) are supplied, separately and in parallel, to the group consisting of four ICs (5a1 to 5a4) and to the group consisting of five ICs (5b1 to 5b5). For convenience of illustration, a clock signal allocated to an IC 5a2 is illustrated as if being supplied by way of an IC 5a1. However, connection is established such that the clock signal is supplied to the IC 5a2 while bypassing the IC 5a1 and such that a clock signal allocated to an IC 5a3 is supplied to the IC 5a3 while bypassing the IC 5a1 and IC 5a2. The same also applies to I/O signals, as well as to the remaining ICs.

When 18 ICs are mounted on the multilayer interconnection board, the ICs are arranged and mounted on the multilayer interconnection boards 1a, 1b in the manner as shown in FIGS. 16A and 16B. Specifically, nine ICs are mounted on the first-layer interconnection board 1a, and nine ICs are mounted on the second-layer interconnection board 1b.

In relation to the connection ICs 50 and the through holes (not shown), the same circuit configuration as shown in FIGS. 14A and 14B is employed, and hence repeated explanations are omitted. Their circuit configurations are as illustrated in FIG. 15.

Signals are supplied to the respective ICs in the same manner as in the circuit configuration shown in FIG. 13. A difference between the circuit configuration shown in FIG. 13 and that shown in FIG. 15 lies solely in that each of the two groups in FIG. 15 consists of nine ICs. Hence, explanation of the circuit configuration shown in FIG. 13 is omitted.

When 36 ICs are mounted on the multilayer interconnection board, the ICs are divided into four groups, each group consisting of nine ICs and arranged and mounted on the multilayer interconnection boards 1a, 1b in the manner shown in FIGS. 18A and 18B. Specifically, two groups; that is, a total of 18 ICs, are mounted on the first-layer interconnection board 1a, and two groups; that is, a total of 18 ICs, are mounted on the second-layer interconnection board 1b. In relation to the connection ICs 50 and the through holes (not shown), the same circuit configuration as shown in FIGS. 14A and 14B is employed, and hence repeated explanations are omitted.

The multilayer interconnection boards have a circuit configuration such as that shown in FIG. 17. The number of parallel circuits for the clock signals (Add, CKEO, /SO-3, and the like) is increased by the amount corresponding to the increase in the number of groups from the circuit configuration shown in FIG. 13. However, the clock signals are supplied to the respective groups in the same manner as in the circuit configuration shown in FIG. 13.

The I/O signals (DQ0 . . . and the like) are supplied in parallel to the ICs of respective groups and electrically identical with those shown in FIG. 13. For convenience of illustration, an I/O signal allocated to, e.g., an IC 5d1, is supplied as if passing through the IC 5b1. However, connection is established such that the I/O signal is supplied to the IC 5d1 while bypassing the IC 5b1. The same also applies to the ICs 5a1 and 5c1 and to the remaining ICs.

Since the related-art memory module is configured in the manner as mentioned above, a lead frame is required, thus adding to material costs. In association with the need for a lead frame, manufacturing processes involve two processes; that is, a process for manufacturing ICs by means of die-bonding a die onto a lead frame, and a process for mounting the ICs onto an interconnection board for a module purpose, thereby resulting in a hike in manufacturing costs. Moreover, if some ICs fail to pass an electric property test, the mold resin and the lead frame used for molding and mounting the ICs to be discarded will become useless.

At the time of mounting ICs on an interconnection board, a circuit configuration and the layout of a multilayer interconnection board change according to the number of ICs to be mounted. Hence, numerous kinds of multi layer inter connection boards must be prepared.

### SUMMARY OF THE INVENTION

The invention has been conceived to solve the drawbacks and aims at providing a COB module which obviates use of a lead frame and in which semiconductor chips (dies), such as memory chips, are mounted directly on a multilayer interconnection board.

The invention also aims at providing a COB module which enables use of the same multilayer interconnection board at the time of mounting dies onto a multilayer interconnection board even when the number of dies has changed and which also enables a reduction in the number of types of multilayer interconnection boards.

The invention also aims at providing a method of manufacturing a COB module, wherein dies mounted on a multilayer interconnection board are subjected to an electric property test before being molded in resin; and, even when some of the dies have failed to pass the test, the board can proceed to the following manufacturing processes without removal of the rejects, by means of eliminating only wires connecting the rejects with the multilayer interconnection board.

According to one aspect of the present invention, a chip-on-board module includes a multilayer interconnection board, a plurality of dies, a plurality of bonding pads, contact pads, jumper pads, and molding resin. The multilayer interconnection board has a plurality of die mount sections. The plurality of dies are to be mounted on respective die mount sections of the multilayer interconnection board such that a single die is mounted on each die mount section or two or more dies are mounted on each die mount section while being stacked. The plurality of bonding pads are provided on the multilayer interconnection board so as to correspond to the respective die mount sections and are connected to single dies or uppermost dies. The contact pads are provided on the multilayer interconnection board so as to correspond to the respective bonding pads and are connected to corresponding bonding pads. The jumper pads are provided in proximity to the contact pads. The jumper pads are connected to edge terminals of the multilayer interconnection board, circuit elements mounted on the multilayer interconnection board, or through holes formed so as to extend across layers of the multilayer interconnection board. The molding resin is molding the dies and the pads. The uppermost dies of the respective die mount sections where dies are stacked in two or more layers have passed an electric property test.

According to another aspect of the present invention, a chip-on-board module includes a multilayer interconnection board, a plurality of dies, a plurality of bonding pads, a plurality of contact pads, through holes, jumper pads, edge terminals, and molding resin. The multilayer interconnection board includes a plurality of layers of interconnection boards. The plurality of die mount sections are provided on an primary-surface-side interconnection board and on an other-surface-side interconnection board. The plurality of dies are mounted on the respective die mount sections provided on the primary-surface-side interconnection board and on those provided on the other-surface-side inter connection board. The plurality of bonding pads are provided on the primary-surface-side interconnection board and the other-surface-side interconnection board so as to correspond to the respective dies and are connected to corresponding dies. The plurality of contact pads are provided on both the primary-surface-side interconnection board and the other-surface-side interconnection board so as to correspond to the bonding pads and are connected to corresponding bonding pads. The through holes are provided so as to extend across the primary-surface-side interconnection board and the other-surface-side interconnection board. The jumper pads are provided on the primary-surface-side interconnection board and the other-surface-side interconnection board in proximity to the contact pads and are connected to the through holes. The edge terminals are provided on either or both of the primary-surface-side interconnection board and the other-surface-side interconnection board and are connected to the through holes. The molding resin is molding the dies and the pads provided on the primary-surface-side interconnection board and those provided on the other-surface-side interconnection board.

According to another aspect of the present invention, a method of manufacturing a chip-on-board module includes the following steps. Dies are mounted on a plurality of die mount sections of a multilayer interconnection board. A plurality of bonding pads corresponding to the respective dies and contact pads corresponding to the respective bonding pads are provided on the multilayer interconnection board. The dies and the corresponding bonding pads are connected together. The bonding pads and the corresponding contact pads are connected together. The respective contact pads are connected to a tester, thereby the respective dies are subjected to an electric property test. Connection are broken between dies that have failed the test and bonding pads corresponding thereto, and a die which has been subjected to and passed the test is stacked on a rejected die. The dies and the pads are molded.

According to the present invention, a chip-on-board module can be formed without use of a lead frame. Further, dies are subjected to the electric property test before being molded. Hence, even when some dies have failed the test, molding resin is not wasted. The dies that have failed to pass the electric property test are left in unmodified form on the multilayer interconnection board, and only connection wires of the rejected dies are removed. Hence, dies which have passed an electric property test performed and targeted separately for only dies are stacked on the rejected dies, and the multilayer interconnection board is molded in resin. Hence, the number of manufacturing steps can be diminished, thereby effectively curtailing costs.

According to the present invention, a multilayer interconnection board can be standardized, thereby enabling an improvement in productivity and curtailing costs.

Other and further objects, features and advantages of the invention will appear more fully from the following description.

### BRIEF DESCRIPTION OF THE DRAWINGS

FIGS. 1A through 1C are schematic illustrations showing the configuration of a first embodiment by reference to an example memory module.

FIG. 2 is a flowchart showing procedures for manufacturing the memory module shown in FIG. 1.

FIG. 3 shows a circuit configuration and the layout of dies required when 36 dies are mounted on the multilayer interconnection board.

FIGS. 4A and 4B show a circuit configuration and the layout of dies required when 36 dies are mounted on the multilayer interconnection board.

FIG. 5 is a schematic representation showing a cross-sectional configuration of a portion of the first-layer interconnection board 1a located in an encircled area in FIG. 4A.

FIG. 6 shows a circuit configuration and the layout of dies required when 18 dies are mounted on the multilayer interconnection board.

FIGS. 7A and 7B show a circuit configuration and the layout of dies required when 18 dies are mounted on the multilayer interconnection board.

FIG. 8 shows a circuit configuration and the layout of dies required when nine dies are mounted on the multilayer interconnection board.

FIGS. 9A and 9B show a circuit configuration and the layout of dies required when nine dies are mounted on the multilayer interconnection board.

FIG. 10 is a schematic representation of a COB module of composite dies

FIGS. 11A and 11B are schematic representations showing the configuration of a related-art chip-on-board (hereinafter abbreviated as a “COB”) module serving as an example of a memory module.

FIG. 12 is a flowchart showing processes for manufacturing the memory module shown in FIG. 11A.

FIG. 13 shows a circuit configuration and an IC layout required when nine ICs are mounted on the multilayer interconnection board.

FIGS. 14A and 14B show a circuit configuration and an IC layout required when nine ICs are mounted on the multilayer interconnection board.

FIG. 15 shows a circuit configuration and an IC layout required when 18 ICs are mounted on the multilayer interconnection board.

FIGS. 16A and 16B show a circuit configuration and an IC layout required when 18 ICs are mounted on the multilayer interconnection board.

FIG. 17 shows a circuit configuration and an IC layout required when 36 ICs are mounted on the multilayer interconnection board.

FIGS. 18A and 18B show a circuit configuration and an IC layout required when 36 ICs are mounted on the multilayer interconnection board.

### DETAILED DESCRIPTION OF THE PREFERRED EMBODIMENTS

### First Embodiment

A first embodiment of the invention will be described by reference to the drawings.

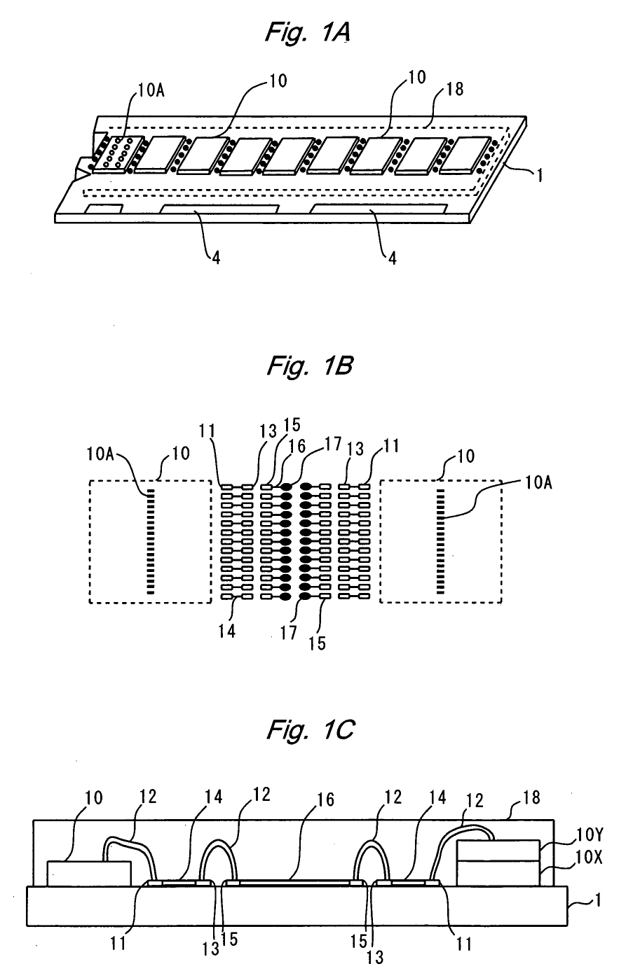

FIGS. 1A through 1C are schematic illustrations showing the configuration of a first embodiment by reference to an example memory module. FIG. 1A is a perspective view showing the overall configuration of a memory module; FIG. 1B is a schematic plan view showing the configuration of two adjacent dies of the configuration shown in FIG. 1A and the configuration of bonding pads, contact pads, and jumper pads provided between the dies; and FIG. 1C is a side cross-sectional view showing the configuration of a multilayer interconnection board shown in FIG. 1B. As shown in the drawings, reference numeral 1 designates a multilayer interconnection board, and a plurality of die mount sections are provided on the surface of the board. Reference numeral 10 designates nine memory chips (dies) fixed on the respective die mount sections. The memory chips (dies) 10 are fixed directly on the multilayer interconnection board 1 without die-bonding the chips on a lead frame, which has been performed conventionally. As shown in the left side in FIG. 1C, a single die 10 is mounted on the multilayer interconnection board 1. Similarly, there is a case where two dies 10X and 10Y are mounted on the multilayer interconnection board 1 while being stacked. The number of dies to be mounted may be two or more, and details of the dies will be described later.

Reference numeral 10A designates pads provided on each die 10; 11 designates bonding pads provided on the multilayer interconnection board 1 corresponding to the respective die mount sections; 12 designates wires for connecting the pads 10A of the dies 10 (or the top die 10Y when two or more dies are stacked) to the bonding pads 11; 13 designates contact pads provided on the multilayer interconnection board 1 corresponding to the bonding pads 11; 14 designates an interconnection pattern for connecting the bonding pads 11 to the contact pads 13; 15 designates jumper pads provided in close proximity to the contact pads 13; and 16 designates interconnection patterns for interconnecting the jumper pads 15. The interconnection patterns 16 are connected with edge terminals 4 which act as terminals for establishing connection with the outside of the multilayer interconnection board. Alternatively, the interconnection patterns 16 are used for connecting together circuit elements (not shown), such as resistors, capacitors, fuses, and like elements mounted on the multilayer interconnection board. Alternatively, the interconnection patterns 16 are routed in the form of a predetermined pattern for establishing connection with through holes 17 formed so as to extend across the multilayer interconnection board and for interconnecting interconnection boards.

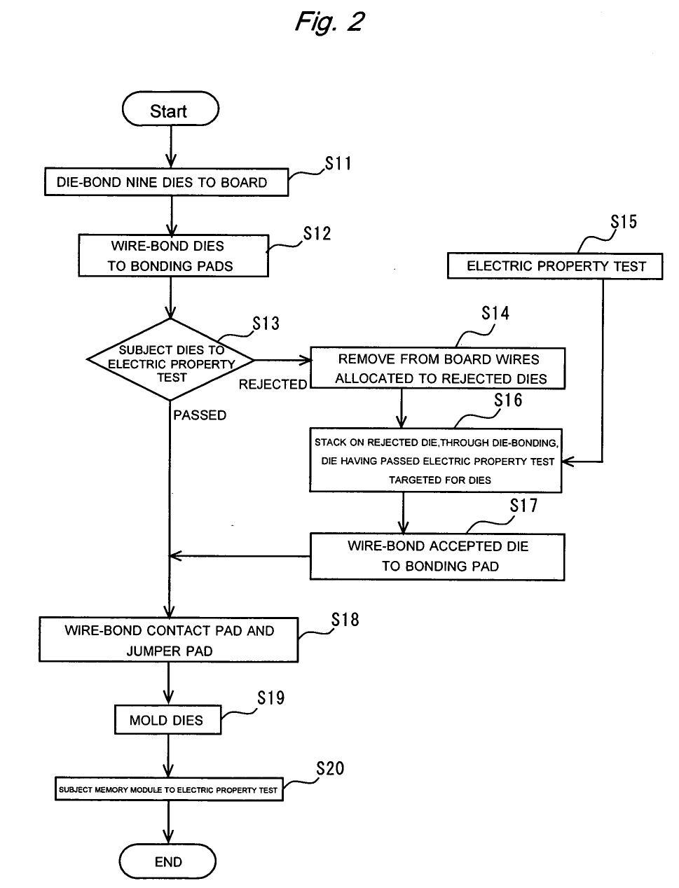

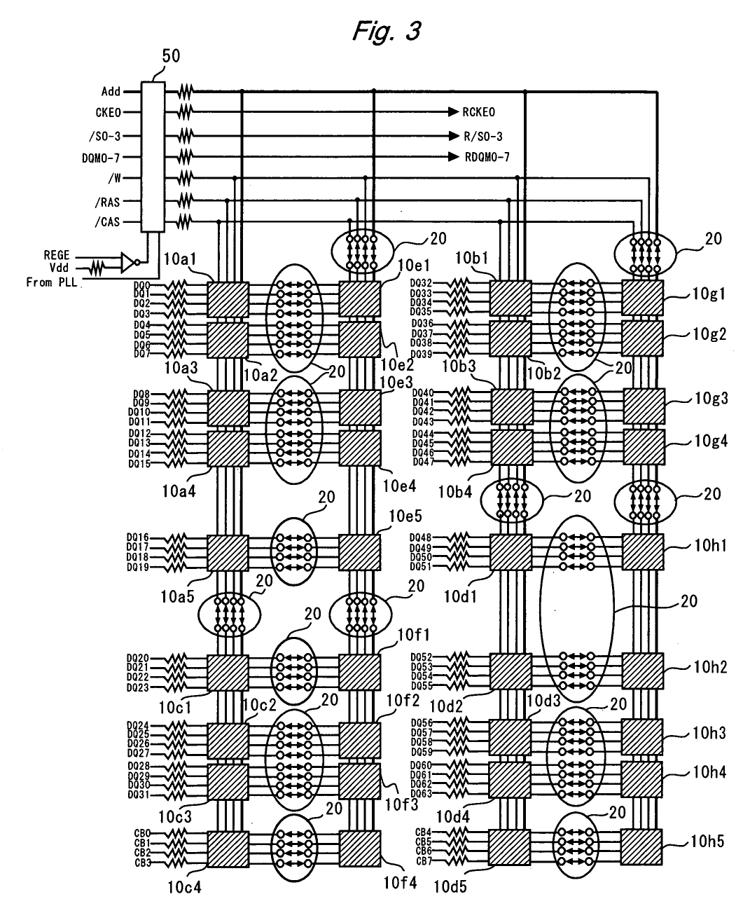

FIG. 2 is a flowchart showing procedures for manufacturing the memory module shown in FIG. 1.

In step S11, nine dies 10 are die-bonded to the multilayer interconnection board 1.

In step S12, the pads 10A of the dies 10 and the bonding pads 11 are wire-bonded together. In step S13, a tester (not shown) is connected to the contact pads 13, thereby subjecting the dies 10 to an electric property test.

Provided that a die 10X shown in FIG. 1C, for example, has not passed the test, in step S14 a wire (not shown) connecting the thus-rejected die 10X to a corresponding bonding pad 11 is disconnected, thereby separating the die 10X from a circuit.

However, as illustrated, the die 10X per se is left in unmodified form on the multilayer interconnection board 1.

In step S15 there is prepared a die 10Y which has passed an electric property test separately performed and targeted for only the dies 10. In step S16, the accepted die 10Y is stacked on the rejected die lox by means of die-bonding. In step S17, a pad of the accepted die 10Y, which is on the top of the stacked dies, is wire-bonded to the corresponding bonding pad 11 in place of the rejected die 10X, thus constituting a circuit. In step S18, the contact pads 13 and the jumper pads 15 are wire-bonded together by means of the wires 12.

In step S19, the dies 10, 10X, 10Y, the bonding pads 11, the contact pads 13, the jumper pads 15, the wires 12, and the interconnection patterns 14, 16, all being provided on the multilayer interconnection board 1, are molded in molding resin 18.

Subsequently, in step S20, the thus-molded assembly is subjected, as a memory module, to an electric property test, thus completing the manufacturing processes.

### Second Embodiment

A second embodiment of the invention will now be described.

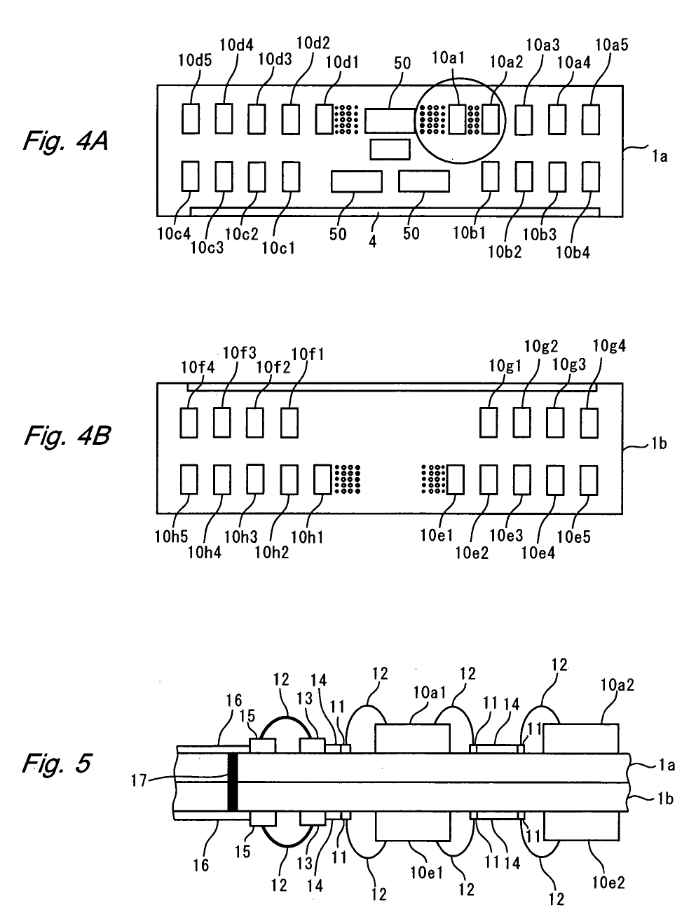

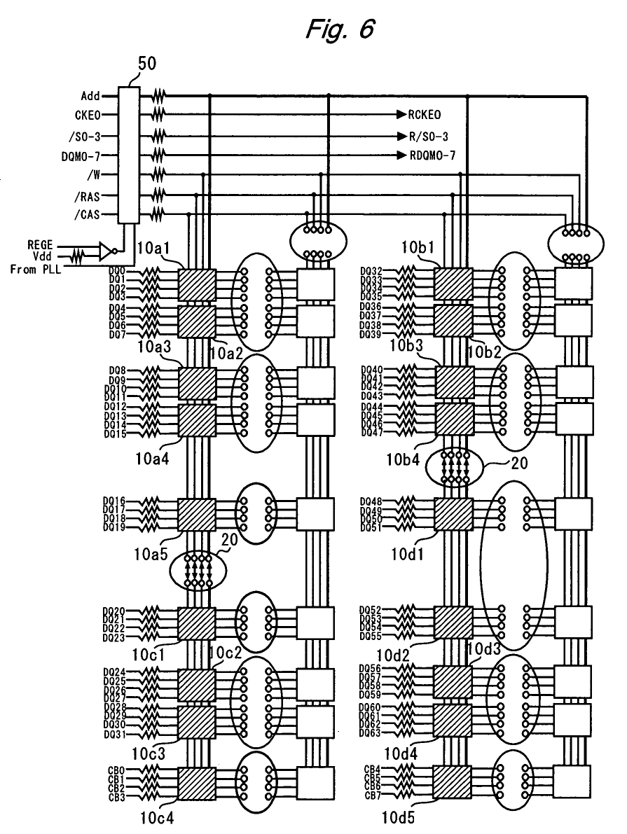

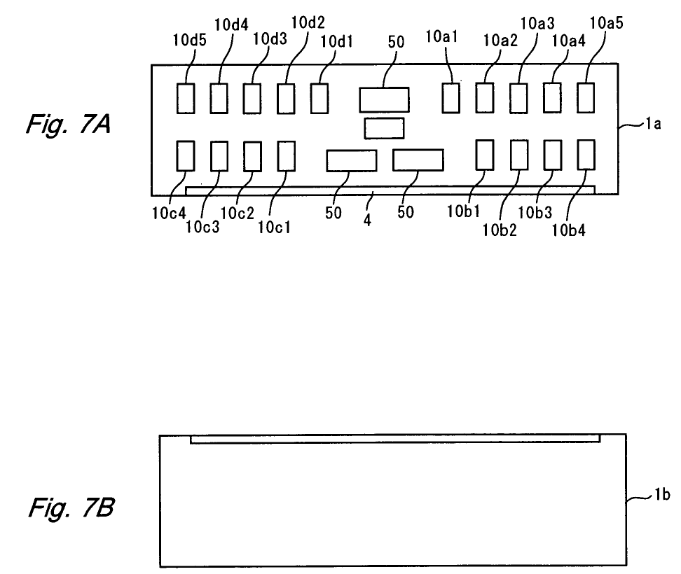

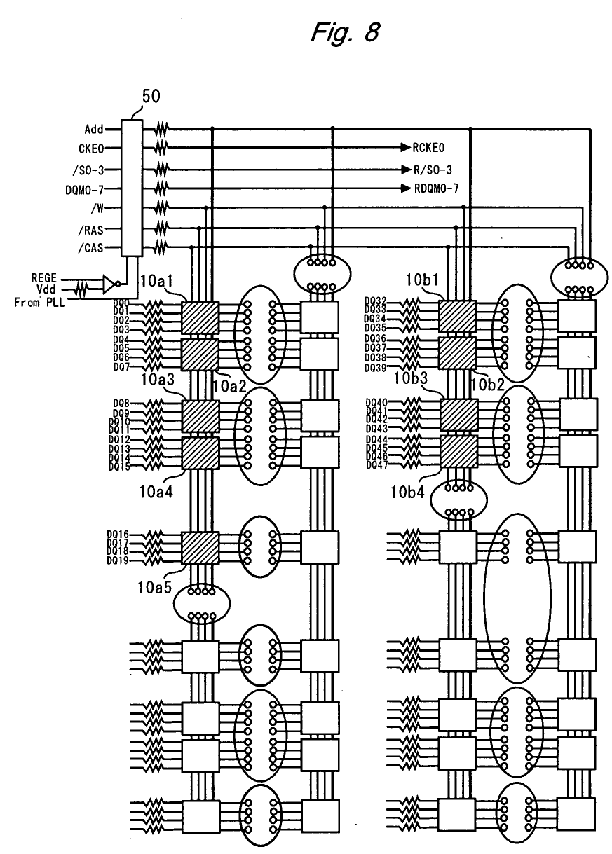

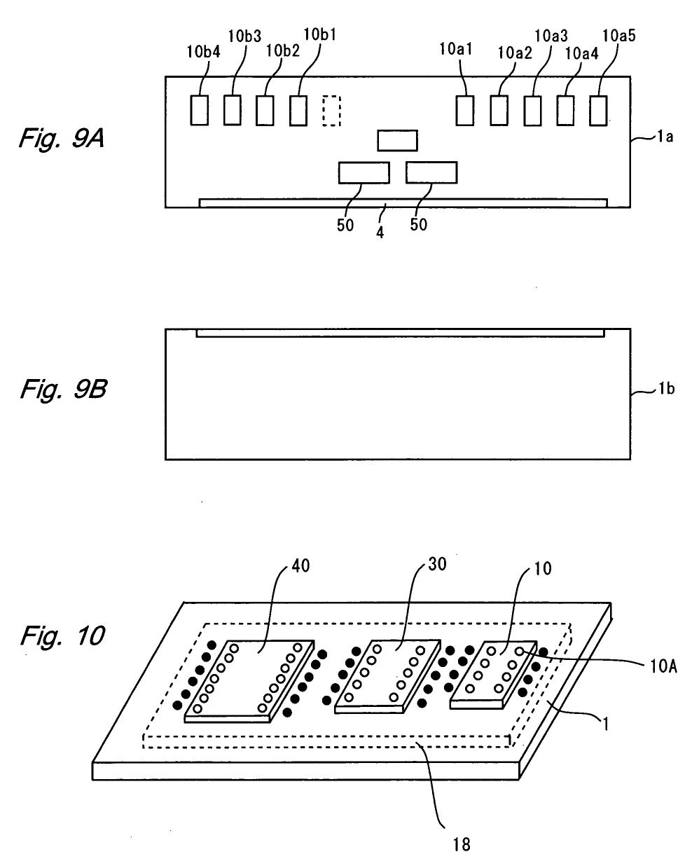

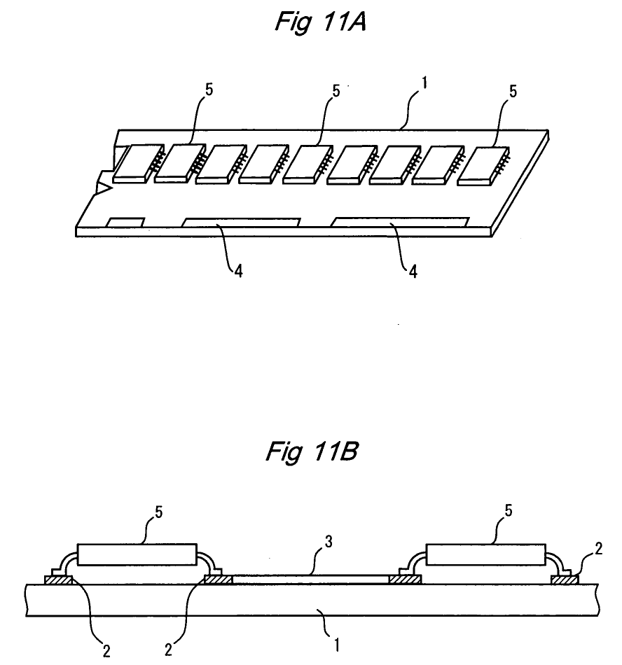

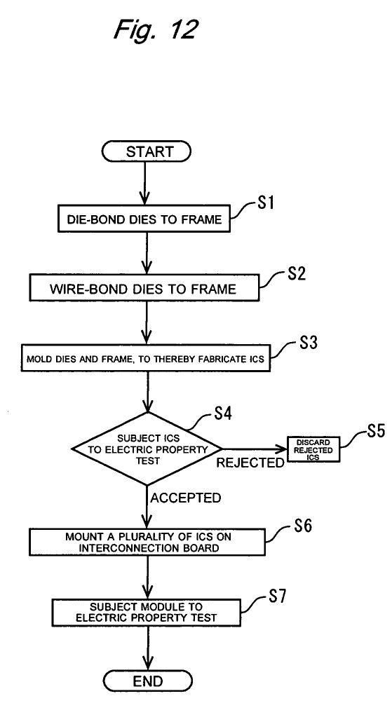

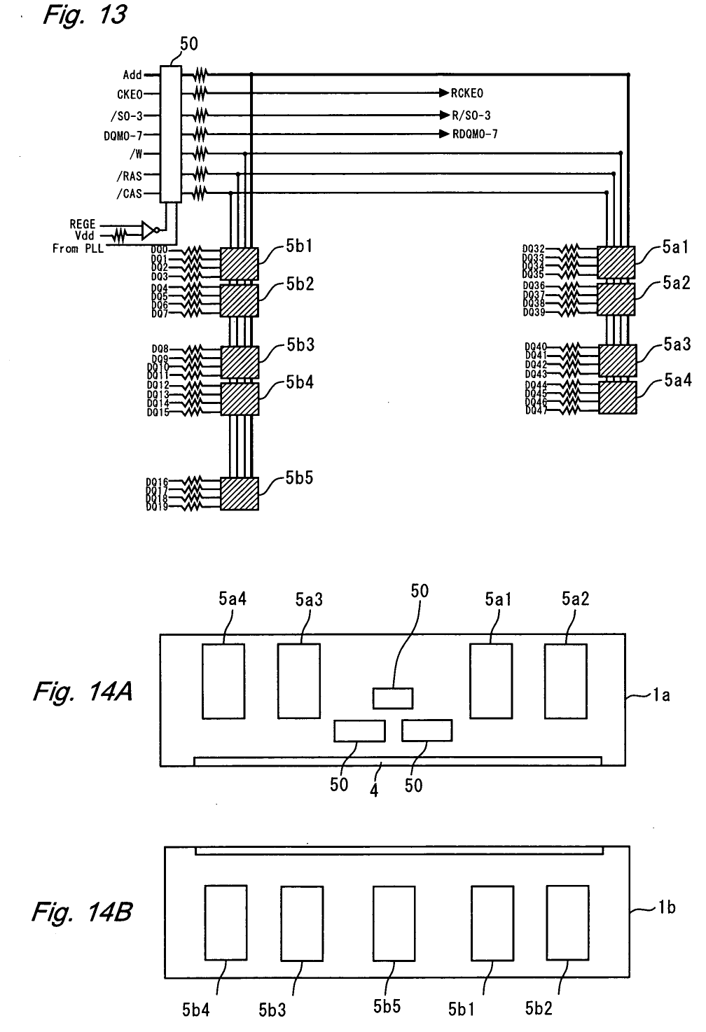

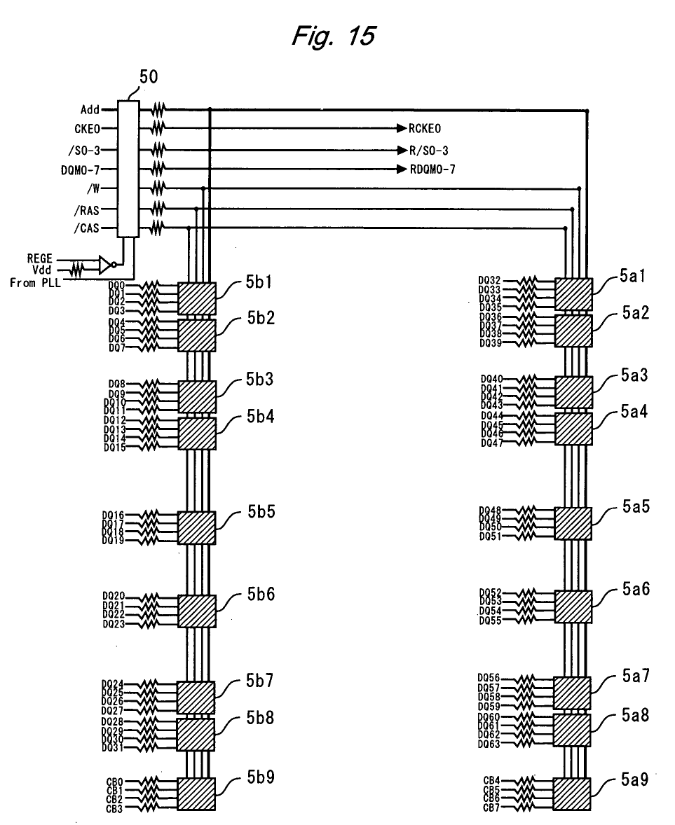

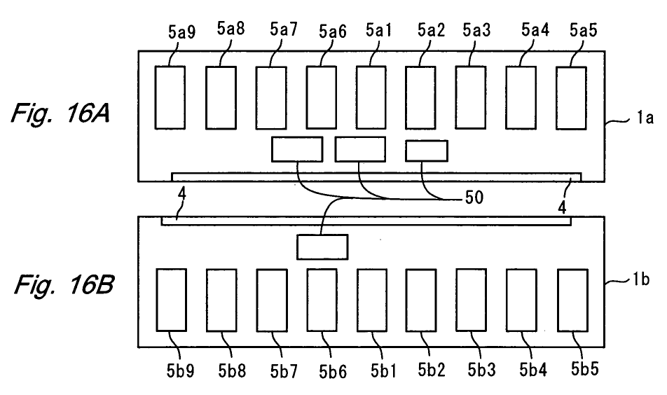

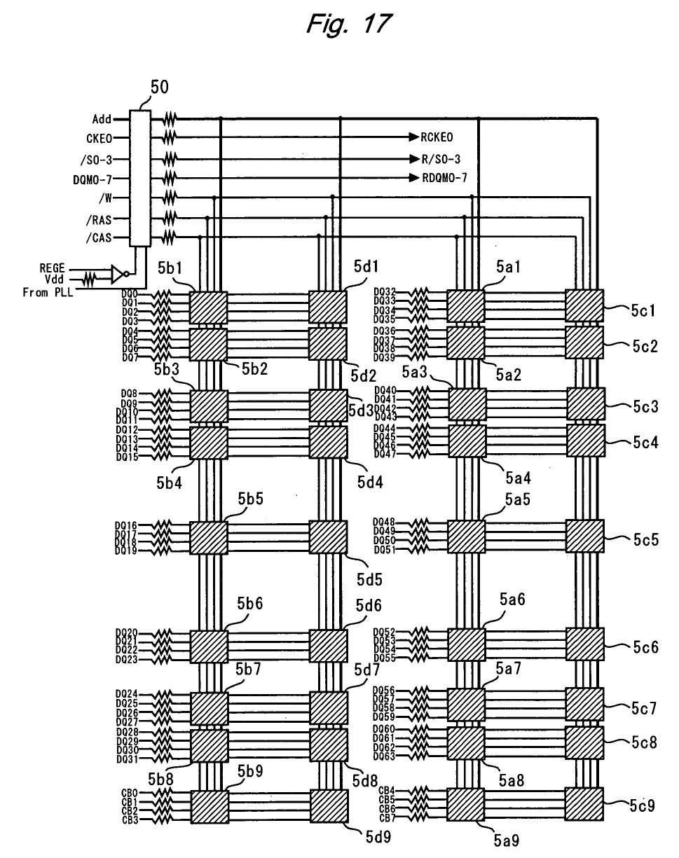

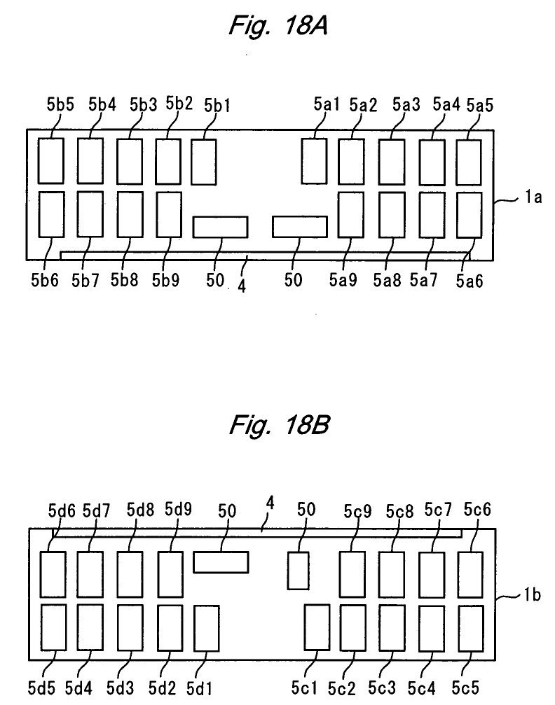

FIGS. 3 through 9 show the configuration of a second embodiment serving as an example memory module. More specifically, FIGS. 3 through 9B are schematic representations showing circuit configurations and layouts of dies 10 required when, in previously-described step S11, the dies 10 are mounted on the multilayer interconnection board 1. FIGS. 3 through 4B show a circuit configuration and the layout of dies 10 required when 36 dies are mounted on the multilayer interconnection board 1. FIGS. 6 through 7B show a circuit configuration and the layout of dies 10 required when 18 dies are mounted on the multilayer interconnection board 1. FIGS. 8 through 9B show a circuit configuration and the layout of dies 10 required when nine dies are mounted on the multilayer interconnection board 1.

First, when 36 dies 10 are mounted on the multilayer interconnection board 1, as shown in FIGS. 4A and 4B, the dies are arranged and mounted on the multilayer interconnection board 1. The drawing illustrates an example of a two-layer multilayer interconnection board 1. FIG. 4A shows a first-layer interconnection board 1a which serves as a front surface, and FIG. 4B shows a second-layer interconnection board 1b which serves as a rear surface. The 36 dies 10 are divided into a total of eight groups (group “a” to group “h”), each group consisting of four or five dies. Four groups of dies; that is, group “a” (10a1 through 10a5), group “b” (10b1 through 10b4), group “c” (10c1 through 10c4), and group “d” (10d1 through 10d5), are arranged on the first-layer interconnection board 1a. The four remaining groups; that is, group “e” (10e1 through 10e5), group “f” (10f1 through 10f4), group “g” (10g1 through 10g4), and group “h” (10h1 through 10h5), are arranged on the second-layer interconnection board 1b.

FIG. 5 is a schematic representation showing a cross-sectional configuration of a portion of the first-layer interconnection board 1a located in an encircled area in FIG. 4A and that of a corresponding portion of the second-layer interconnection board 1b, schematically showing a connection between the first-layer and second layer interconnection boards 1a, 1b and a through hole 17 for connecting the boards together.

Those elements corresponding to those shown in FIG. 1C are assigned the same reference numerals, and hence their repeated explanations are omitted. The drawing shows merely exemplary layout and position of the through hole 17, and the position of the through hole 17 is not limited to the illustrated example. The interconnection boards 1a, 1b assume a circuit configuration such as that shown in FIG. 3. The clock signals (Add, CKEO, /SO-3, and the like) and the I/O signals (DQ0 . . . and the like) are supplied, in parallel, to respective dies of each of the groups.

For the convenience of illustration, a clock signal allocated to, e.g., a die 10a3, is illustrated as if being supplied byway of dies 10a1 and 10a2. However, connection is established such that the clock signal is supplied, in parallel to the dies 10a1 and 10a2, to the die 10a3 while bypassing the dies 10a1 and 10a2. The same also applies to I/O signals, as well as to the remaining dies.

Clock signals are connected so as to be supplied directly to the dies belonging to the group “a” (10a1 through 10a5) and the dies belonging to the group “b” (10b1 through 10b4), while bypassing jumper lines 20. In contrast, clock signals are supplied to dies belonging to the groups “c” through “h” by way of the jumper lines 20.

Connection is established such that I/O signals are supplied directly to the respective dies belonging to the groups “a” through “d” while bypassing the jumper lines 20. In contrast, I/O signals are supplied to the respective dies belonging to the groups “e” through “h” by way of the jumper lines 20. As will be described later, in a case where the number of dies to be mounted on a multilayer interconnection board is decreased and dies of only some groups are connected to the board, if circuits in which no dies are to be mounted are left idle while being in a connected state, the circuits may cause faulty operations. For this reason, the circuits where no dies are mounted can be separated from the other circuits by means of jumper lines.

Next, when 18 dies 10 are mounted on a multilayer interconnection board, as shown in FIG. 7, there is employed the same multilayer interconnection board as that used for mounting 36 dies. In this case, the dies 10 are mounted only on the first-layer interconnection board 1a, and no dies are mounted on the second-layer interconnection board 1b.

The dies 10 are arranged on the first-layer interconnection board 1a in the same manner as shown in FIG. 4A; that is, a total of 18 dies belonging to the groups “a” through “d, ” are arranged. In this case, as shown in FIG. 6, a circuit configuration is established such that dies belonging to only the groups “a” through “d” hatched in the drawing are connected to signal sources. All jumper lines 20 to be connected to clock signal terminals and I/O signal terminals of areas where dies of the groups “e” through “h” are mounted are disconnected.

As shown in FIGS. 9A and 9B, when nine dies 10 are mounted, there is used the same multilayer interconnection board as that used in mounting 36 dies. The dies 10 are mounted solely on the first-layer interconnection board 1a, and no dies are mounted on the second-layer interconnection board 1b. In this case, there is established a circuit configuration such as that shown in FIG. 8. Nine dies (hatched in FIG. 8), which can be connected to signal sources while bypassing the jumper line 20 and which belong to the groups “a” and “b,” are arranged in the manner shown in FIG. 9A. Areas designated by broken lines are unoccupied. As shown in FIG. 8, all the jumper lines 20 are disconnected, as are all connection lines other than those of the dies belonging to the groups “a” and “b.”

The embodiments have been described by reference to an example memory module. However, the invention is not limited to the memory module; the invention can be applied to a microcomputer chip or an ASIC chip in the same manner. FIG. 10 is a schematic representation of a COB module of composite dies, wherein a memory chip 10, an ASIC chip 30, and a microcomputer chip 40 are mounted on the multilayer interconnection board 1. Since the COB module is manufactured in the same manner as are the previously-described memory modules, repeated explanations thereof are omitted.

A chip-on-board module according to the invention comprises a multilayer interconnection board having a plurality of die mount sections; a plurality of dies which are to be mounted on respective die mount sections of the multilayer interconnection board such that a single die is mounted on each die mount section or two or more dies are mounted on each die mount section while being stacked; a plurality of bonding pads which are provided on the multilayer interconnection board so as to correspond to the respective die mount sections and connected to single dies or uppermost dies; contact pads which are provided on the multilayer interconnection board so as to correspond to the respective bonding pads and are connected to corresponding bonding pads; jumper pads which are provided in proximity to the contact pads and are connected to edge terminals of the multilayer interconnection board, circuit elements mounted on the multilayer interconnection board, or through holes formed so as to extend across layers of the multilayer interconnection board; and molding resin for molding the dies and the pads, wherein the uppermost dies of the respective die mount sections where dies are stacked in two or more layers have passed an electric property test. A COB module, such as a memory module, can be formed without use of a lead frame. Further, dies are subjected to the electric property test before being molded. Hence, even when some dies have failed the test, molding resin is not wasted. The dies that have failed to pass the electric property test are left in unmodified form on the multilayer interconnection board, and only connection wires of the rejected dies are removed. Hence, dies which have passed an electric property test performed and targeted separately for only dies are stacked on the rejected dies, and the multilayer interconnection board is molded in resin. Hence, the number of manufacturing steps can be diminished, thereby effectively curtailing costs.

According to the COB module of the invention, dies to be mounted on die mount sections of the multilayer interconnection board are divided into a plurality of groups. Dies belonging to a predetermined group receive signals while bypassing jumper lines. However, dies belonging to the other groups receive signals by way of jumper lines. Hence, the chance of occurrence of faulty operations is reduced, thereby enabling an improvement in reliability.

A chip-on-board module according to the invention comprises a multilayer interconnection board which includes a plurality of layers of interconnection boards and in which a plurality of die mount sections are provided on an interconnection board constituting a primary surface and on an interconnection board constituting another surface; a plurality of dies mounted on the respective die mount sections provided on the primary surface and on those provided on the other surface; a plurality of bonding pads which are provided on the primary-surface-side interconnection board and the other-surface-side interconnection board so as to correspond to the respective dies and which are connected to corresponding dies; a plurality of contact pads which are provided on both the primary-surface-side board and the other-surface-side board so as to correspond to the bonding pads and which are connected to corresponding bonding pads; through holes provided so as to extend across the primary-surface-side board and the other-surface-side board; jumper pads which are provided on the primary-surface-side board and the other-surface-side board in proximity to the contact pads and are connected to the through holes; edge terminals which are provided on either or both of the primary-surface-side board and the other-surface-side board and which are connected to the through holes; and molding resin to be used for molding the dies and the pads provided on the primary-surface-side board and those provided on the other-surface-side board. Hence, a multilayer interconnection board can be standardized, thereby enabling an improvement in productivity and curtailing costs.

Obviously many modifications and variations of the present invention are possible in the light of the above teachings. It is therefore to be understood that within the scope of the appended claims the invention may by practiced otherwise than as specifically described.

The entire disclosure of a Japanese Patent Applications No. 2000-259661, filed on Aug. 29, 2000 and No. 2002-57653, filed on Mar. 4, 2002 each including specification, claims, drawings and summary, on which the Convention priority of the present application is based, are incorporated herein by reference in its entirety.

1-7. (canceled)

8. A method of manufacturing a semiconductor device, comprising the steps of:
providing a circuit board having a plurality of die mount sections, a plurality of bonding pads corresponding to the respective die mount sections, contact pads connected to corresponding bonding pads, and jumper pads positioned proximate to said contact pads and not electrically connected to corresponding contact pads;
providing a plurality of semiconductor chips each having a plurality of electrode pads;
bonding the plurality of semiconductor chips on corresponding die mount sections and electrically connecting the plurality of semiconductor chips to the corresponding bonding pads;
testing electric properties of the plurality of semiconductor chips;
after the testing step, electrically connecting the jumper pads with the corresponding contact pads.

9. The method of manufacturing a semiconductor device according to claim 8, wherein, further comprising the step of sealing the plurality of semiconductor chips with molding resin.

10. The method of manufacturing a semiconductor device according to claim 9, wherein, after the testing step and before the sealing step, further comprising the step of replacing a defective chip of the plurality of semiconductor chips with another semiconductor chip.

11. The method of manufacturing a semiconductor device according to claim 9, wherein, after the sealing step, further comprising the step of testing electronic properties of the semiconductor device.

12. The method of manufacturing a semiconductor device according to claim 8, wherein, in the jumper pads electrically connecting step, electrically connecting each of the plurality of semiconductor chips with another circuit element on the circuit board through the jumper pads.

13. The method of manufacturing a semiconductor device according to claim 8, wherein, in the jumper pads electrically connecting step, electrically connecting each of the plurality of semiconductor chips with external terminals of the circuit board through the jumper pads.

14. The method of manufacturing a semiconductor device according to claim 8, wherein, in the jumper pads electrically connecting step, electrically connecting the jumper pads with the corresponding contact pads via jumper wires.

15. The method of manufacturing a semiconductor device according to claim 8, wherein, each of the plurality of semiconductor chips is a memory chip.

16. The method of manufacturing a semiconductor device according to claim 8, wherein, the plurality of semiconductor chips are electrically connected to the corresponding bonding pads through bonding wires.

17. The method of manufacturing a semiconductor device according to claim 8, wherein, in the testing step, contacting a test connector to the contact pads.
